(19) United States
(12) Patent Application Publication
(10) Pub. No.: US 2008/0080141 A1
(43) Pub. Date: Apr. 3, 2008

(54) Electrical Circuit Package

(76) Inventors: Hans-Joachim Krokoszinski, Garching (DE); Jens Helfrich, Speyer (DE); Rolf Disselnkotter, Mauer (DE)

Correspondence Address: James E. Bradley;Bracewell & Patterson, L.L.P., P O Box 61389, Houston, TX, 77208-1389, US

(21) Appl. No.: 11/663,573

(22) PCT Filed: Aug. 4, 2005
(86) PCT No.: PCT/GB05/03288

§ 371 Date: Mar. 23, 2007

(30) Foreign Application Priority Data
Sep. 23, 2004 (GB) 0421131.4

(51) Int. Cl. H05K 7/20; H05K 3/30

(52) U.S. Cl. 361/709; 29/832

(57) ABSTRACT

An electrical circuit package comprises a ceramic substrate (1) with an electrical circuit pattern formed on one surface thereof, an opposite surface of the substrate being metallized, and an electrically conductive platelet (2) and a conductor body (3), arranged so that a first face of the platelet is soldered to the metallized surface of the substrate and an opposite face of the platelet is affixed in contact with the conductor body. A method of constructing the package is also described.

The present invention relates to an electrical circuit package, for example an electronic hybrid package, and a method for constructing such a package.

Electronic systems for harsh environments, for example sub-sea and downhole oil field exploration and completion, must simultaneously withstand high temperatures and vibration levels during their complete lifetime. In addition, high shock levels may occur during transport and system installation. Suitable technologies for power electronic systems with relatively large and heavy components such as capacitors, magnetic devices etc, which are able to withstand temperatures >150° C. and high acceleration (e.g. more than 100 g) are currently not available.

It is an aim of the present invention to provide an electrical circuit package which can withstand harsh environments, for example temperatures in excess of 150° C. and high vibration and acceleration levels.

In accordance with a first aspect of the present invention, there is provided an electrical circuit package comprising a ceramic substrate with an electrical circuit pattern formed on one surface thereof, an opposite surface of the substrate being metallized, and an electrically conductive platelet and a conductor body, arranged so that a first face of the platelet is soldered to the metallized surface of the substrate and an opposite face of the platelet is affixed in contact with the conductor body.

Advantageously, the platelet and the substrate have substantially similar thermal expansion coefficients.

Preferably, the solder is substantially flexible.

The platelet may comprise aluminium silicon carbide.

The substrate may comprise aluminium oxide.

The ceramic substrate may be at least partially covered in a deformable mould, such as silicone gel.

Advantageously, the package comprises a conductive housing, for example made from steel.

The substrate, platelet and conductor body may be at least partially encased in a rigid mould, for example of silicone.

The ceramic substrate may comprise at least one electrical component affixed thereto, for example by soldering. The component may additionally be mechanically affixed to the platelet and/or the conductor body by a clamp.

At least one electrical component may be affixed directly to the conductor body.

Preferably, the conductor body comprises copper.

At least one further substrate and platelet may be provided within the package. The substrates may be electrically interconnected via flexible metallic couplings, for example nickel strips.

In accordance with a second aspect of the present invention, there is provided a method of constructing an electrical circuit package comprising the steps of:

providing a ceramic substrate with an electrical circuit pattern formed on one surface thereof and the other surface being metallized;

providing an electrically conductive platelet;

soldering the metallized surface of the substrate to a face of the platelet; and

affixing the platelet to a conductor body.

The method may comprise the step of at least partially covering the substrate in a deformable mould.

The method may comprise the step of encasing the substrate, platelet and conductor body in a rigid mould.

The method may comprise the step of providing a metallic housing for the package.

The invention will now be described with reference to the accompanying figures, in which:

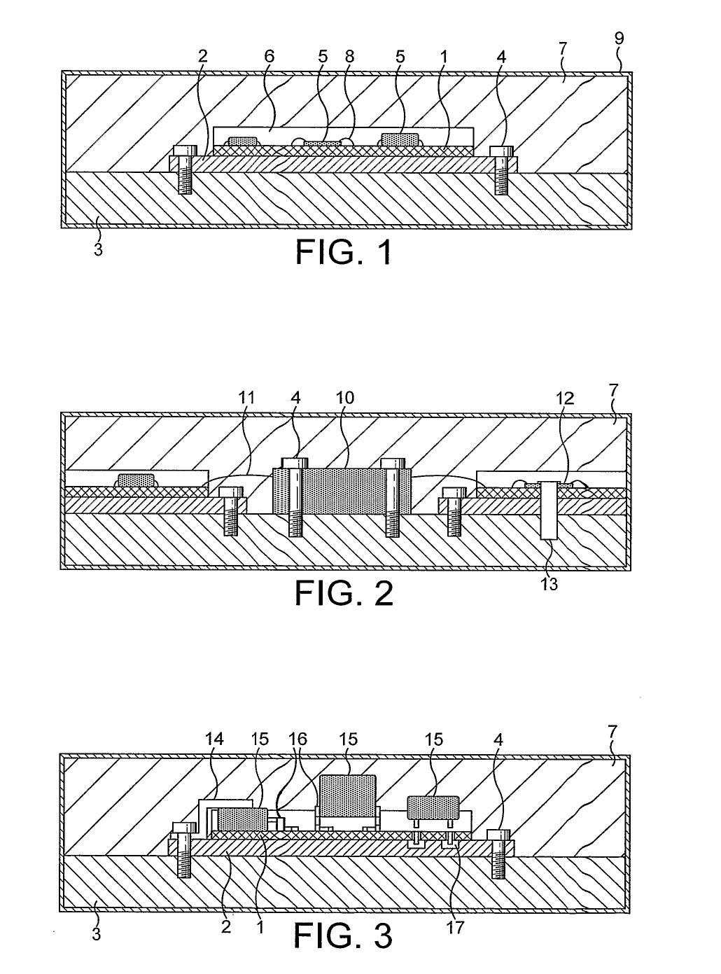

FIGS. 1-3 show sectional views of various electrical circuit packages in accordance with the present invention.

FIGS. 1 to 3 show three embodiments of electrical circuit packages in accordance with the present invention. An electronic circuit, for example an electronic thick film hybrid is fabricated on a ceramic substrate 1. The circuit may include various relatively small surface-mounted electrical components 5, e.g. dies. So that the circuit may operate in harsh environments, the circuit must be capable of withstanding high temperatures, for example in excess of 150° C. A suitable hybrid circuit capable of doing so is described in co-pending UK Patent Application “Thick-film Hybrid Production Process” by the present applicant. The circuits described therein use Al₂O₃ ceramic substrates. The underside of the substrate is metallized and then soldered onto a conductive platelet 2, for example of aluminium silicon caxbide (AlSiC). A high temperature, flexible solder such as Pb95Sn5 with melting temperatures >300° C. may be used to allow operation in high ambient temperatures. The AlSiC platelet has a similar thermal expansion coefficient as the A1₂0₃ ceramic, which minimizes the mechanical stress during thermial cycling. In addition, assuming the substrates are not too large, high temperature, flexible solder alloy will balance the small remaining thermal mismatch. The AlSiC platelets also serve as a heat spreader due to their very high thermal conductivity. The surface of the hybrid with the small and susceptible components, for example semiconductor dies, is protected with a deformable mould such as soft silicone gel 6.

The complete hybrid with the AlSiC platelet is mounted on a massive, good thermal conductive copper body 3 and fixed with screws 4. Relatively large and heavy components 10 such as bulky capacitor stacks or magnetic components (e.g. inductors, transformers), which are too large for direct placement on the substrate or are not surface mountable are placed directly on the copper body and are fixed by screws. FIG. 2 shows such a component fitted between and connected to two adjacent hybrids. The electrical interconnection to the hybrids is achieved by flexible nickel strips 11.

If a large thermal mismatch exists between surface mountable devices and the ceramic substrate or if some components are not able to withstand the soldering process, these components can be placed on the substrate upside down 12 and be can mechanically fixed with a U-shaped metal clamp 13, which is mounted to the copper body from the side and is electrical connected to the substrate by thick wire bonds or micro-welded nickel strips. The metal clamp can also be soldered to the substrate in a first step (fixation) and the component can afterwards be placed underneath.

Relatively large components 15, which may also have wire leads, must have a good mechanical fixation to eliminate large forces to the electrical solder points during high shocks. This is necessary to prevent cracks in the interconnection, i.e. solder or thick film conductor. Additionally, the electrical connection to the component should be flexible, to balance different thermal expansions of the component and substrate materials. This is achieved by using wire leads or studs 16, which are soldered to the substrate. If the studs of the device cannot be bent for surface mounting, a hole may be laser drilled through the ceramic substrate 1 where the wire leads are fed through and additionally fixed on the backside by soldering, gluing or moulding. At the feed- through, the electrically conductive AlSiC platelet has holes or depressions 17 which may also be laser drilled, which are large enough to prevent short circuits between the wires.

The components 15 may be fixed and kept in place by s-shaped metallic clamps 14, which are fixed by screws to the AlSiC platelet or directly to the copper body. Alternatively and/or additionally they may be fixed by a hard mould 7, e.g. a silicone, which is filled into the complete surrounding housing 9, e.g. made of steel, at vacuum. This mould will also act as a damping material against resonant oscillations of the large components. The mould is particularly advantageous for mechanically fixing components with wire lead connections as it protects the leads, preventing movement.

Although the invention has been described with reference to the embodiments above, there are many other modifications and alternatives possible within the scope of the claims. In particular, the materials mentioned in the description are examples of materials which offer operability in harsh environments. Any other materials may be used which provide similar levels of operability.

1. An electrical circuit package comprising a ceramic substrate with an electrical circuit pattern formed on one surface thereof, an opposite surface of the substrate being metallized, and an electrically conductive platelet and a conductor body, arranged so that a first face of the platelet is soldered to the metallized surface of the substrate and an opposite face of the platelet is affixed in contact with the conductor body.

2. A package according to claim 1, wherein the platelet and the substrate have substantially similar thermal expansion coefficients.

3. A package according to claim 1, wherein the solder is substantially flexible.

4. A package according to claim 1, wherein the platelet comprises aluminum silicon carbide.

5. A package according to claim 1, wherein the substrate comprises aluminum oxide.

6. A package according to claim 1, wherein the ceramic substrate is at lease partially covered in a deformable mould.

7. A package according to claim 6, wherein the deformable mould comprises silicone gel.

8. A package according to Cam1 any preceding claim, wherein the package comprises a conductive housing.

9. A process according to claim 8, wherein the housing comprises steel.

10. A package according to claim 1, wherein the substrate, platelet and conductor body are at lease partially encased in a rigid mould.

11. A package according to claim 10, wherein the rigid mould comprises silicone.

12. A package according to claim 1, wherein the ceramic substrate comprises at lease one electrical component affixed thereto.

13. A package according to claim 12, wherein the at least one electrical component is electrically connected to the substrate by soldering.

14. A package according to claim 12 either of claims 12 and 13, wherein the at least one electrical component is mechanically affixed to the platelet and/or the conductor body by a clamp.

15. A package according to claim 1, wherein at least one electrical component is affixed directly to the conductor body.

16. A package according to claim 1, wherein the conductor body comprises copper.

17. A package according to claim 1, comprising at least one further substrate and platelet.

18. A package according to claim 17, wherein the substrates are electrically interconnected via flexible metallic couplings.

19. A package according to claim 18, wherein the couplings comprise nickel strips.

20. A method of constructing an electrical circuit package comprising the steps of:
providing a ceramic substrate with an electrical circuit pattern formed on one surface thereof and the other surface being metallized;
providing an electrically conductive platelet;
soldering the metallized surface of the substrate to a face of the platelet; and
affixing the platelet to a conductor body.

21. A method according to claim 20, comprising the step of at lease partially covering the substrate in a deformable mould.

22. A method according to claim 20, comprising the step of encasing the substrate, platelet and conductor body in a rigid mould.

23. A method according to claim 20, comprising the step of providing a metallic housing for the package.

24. (canceled)

25. (canceled)
